(19) United States
(12) Patent Application Publication
(10) Pub. No.: US 2011/0001169 A1
(43) Pub. Date: Jan. 6, 2011

(54) FORMING UNIFORM SILICIDE ON 3D STRUCTURES

(75) Inventors: Ahmet S. Ozcan, Hopewell Junction, NY (US); Christian Lavoie, Yorktown Heights, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/495,989

(22) Filed: Jul. 1, 2009

(51) Int. Cl. H01L 29/49; H01L 21/3205

(52) U.S. Cl. 257/213; 438/655; 438/653; 257/E21.296; 257/E29.156

(57) ABSTRACT

By using a non-conformal diffusion barrier in conjunction with a similarly deposited non-conformal initial deposition of siliciding material, a substantially uniform and conformal silicide can be formed in a 3D structure such as the fin of a FinFET. The siliciding material may be nickel (Ni), the diffusion barrier may be titanium (Ti) or titanium nitride (TiN). Generally, the diffusion barrier may be any material which will inhibit, but not block, diffusion of the siliciding material into the silicon. In this manner, a non-conformal barrier deposition, in conjunction with a non-conformal silicide material deposition, after anneal, results in substantially conformal silicide formation.

### BACKGROUND

The present invention generally relates to semiconductor device fabrication and, more particularly, to siliciding three-dimensional (3D) structures such as FinFETs.

The fabrication of microelectronic semiconductor devices, commonly referred to as integrated circuits (ICs) may generally involve the processes of depositing materials on and removing materials from a semiconductor substrate such as a silicon wafer. Other processes such as diffusion, annealing may also be involved. Some of these materials and processes may be described herein. Generally, the individual processes which are involved are well known.

The semiconductor substrate, typically in the form of a wafer, may be a semiconductor material such as silicon, germanium, silicon germanium, silicon carbide, and those consisting essentially of III-V compound semiconductors such as GaAs, II-VI compound semiconductors such as ZnSe. Silicon on insulator (SOI) technology refers to the use of a layered silicon-insulator-silicon substrate in place of a conventional “bulk” silicon substrate in semiconductor manufacturing, especially microelectronics. SOI-based devices differ from conventional silicon-built devices in that the silicon junction is above an electrical insulator, typically oxide or (less commonly) sapphire.

Materials may include electrically conductive (conductor) materials and electrically insulative (dielectric) materials. Conductive materials are typically metals, such as aluminum, copper, gold, nickel, titanium and tungsten. Some examples of dielectric materials are oxide (silicon dioxide; chemical formula SiO2) and nitride (silicon nitride; “SiN”; chemical formula Si3N4). In recent years, a number of “high k” dielectric materials have been developed which have a high dielectric constant (k).

Various deposition processes are known, including but not limited to:

Chemical vapor deposition (CVD), which is a chemical process used to produce high-purity, high-performance solid materials. The process is often used in the semiconductor industry to produce thin films. In a typical CVD process, the wafer (substrate) is exposed to one or more volatile precursors, which react and/or decompose on the substrate surface to produce the desired deposit. CVD is used to deposit materials in various forms, including: monocrystalline, polycrystalline, amorphous, and epitaxial. These materials include: silicon, oxide, nitride and metals, such as are commonly used in semiconductor fabrication.

Sputter deposition, which is one of the most widely used techniques for the fabrication of thin-film structures on semiconductor wafers. It is used primarily for the deposition of metal thin films used to form vias and lines, as well as the various related thin films which function as diffusion barriers, adhesion or orientation layers, seed layers, primary conductors, antireflection coatings, and etch stops. Sputter deposition is usually carried out in diode plasma systems known as magnetrons, in which the cathode is sputtered by ion bombardment and emits the atoms, which are then deposited on the wafer in the form of a thin film. Depending on the lithography scheme, these films may then be etched by means of reactive ion etching (RIE) or polished using chemical-mechanical polishing (CMP) to help delineate circuit features.

Various patterns of materials which have been deposited may selectively be formed using processes such as photolithography, which generally involves coating the device with a layer of a material such as photoresist which may be patterned to form a mask, then etching underlying materials which are not covered by the photoresist such as with a chemical, then removing the photoresist mask and proceeding with further processing steps. Typically, the photoresist, which is applied temporarily and is then removed, does not form an element of the final product. Sometimes the photoresist mask is used to pattern an underlying material, such as nitride, to serve as a mask for a subsequent process.

In some cases, underlying structures themselves may function as a mask function. For example, when performing source/drain (S/D) diffusions, oxide sidewall spacers on a polysilicon gate of a field effect transistor (FET) can cause the S/D diffusions in the substrate to be spaced more widely apart, thereby increasing the channel length. When a process utilizes a pre-existing structure as a mask, the process may be referred to as “self-aligned”.

Materials may be diffused, or implanted into the substrate (or into other elements such as polysilicon lines and structures) to control the conductivity and polarity of the substrate (or an area thereof), such as for creating the aforementioned S/D diffusions. For example, elements such as boron (B) and indium (In) may be implanted into silicon to create p-type (or electron acceptor) semiconductor material, and elements such as phosphorous (P) arsenic (As) and antimony (Sb) may be implanted into silicon to create n-type (or electron donor) semiconductor material.

Etching generally refers to the removal of material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch.

Wet etch is performed with a solvent (such as an acid) which may be chosen for its ability to selectively dissolve a given material (such as oxide), while leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically.

Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as STI trenches.

Using such processes and materials, various semiconductor elements and structures may be formed, an exemplary one of which is the field effect transistor (FET). A conventional field effect transistor (FET) may comprise a “channel” defined between two spaced-apart source/drain (S/D) diffusions in a silicon layer (which may be a silicon substrate, or a silicon layer on an underlying insulating layer), and a gate electrode (or simply “gate”) disposed on the channel (and insulated therefrom by a thin gate oxide layer). Voltage applied to the gate electrode exerts a field effect in the channel, controlling the flow of current from source (S) to drain (D). To give a very rough, very general sense of scale and proportion to things, a conventional FET may have a channel length (distance between the source and drain diffusions) of approximately 100 nm (nanometers), and the gate oxide may be only tens of angstroms (Å) thick. (1 nm=10 Å). A human hair may typically have a thickness of approximately 100 μm (microns). (1 μm=1000 nm=10000 Å). In other words, approximately 1000 FETs could be formed across the thickness of a single human hair.

Trenches may be etched into the substrate, and filled with another material. An example is shallow trench isolation (STI) which may involve forming a trench around one or more transistors, and filling the trench with a dielectric material such as oxide to electrically isolate the transistors within an area bordered by the filled trench from other transistors which are outside the borders of the trench.

After all of the devices (such as FETs) have been completely formed, they will need to be connected with one another. A relatively thick layer of inter-level (or inter-layer) dielectric (ILD) may be formed comprising one or more layers of oxide deposited on the underlying structures (such as FETs), which will support one or more layers of conductive metal lines interconnecting the various underlying structures. In a manner similar to forming trenches, openings, or “vias” may be etched through the various layers the ILD and filled with metal (such as aluminum or copper) to make contact with elements (such as source, drain, gate) of the underlying structures, as well as between metal lines in various layers of the ILD. When making contact to underlying structures, such as the source or drain diffusions (in silicon), or the gate electrode (typically polysilicon) of an FET, the structure (which is typically silicon), may first be “silicided”.

Silicides are alloys of silicon (Si) and metal which may be used as contact material in silicon device manufacturing. Various metals (“siliciding materials”) which may be alloyed with silicon include cobalt (Co, resulting in CoSi2), titanium (Ti, resulting in TiSi2), platinum (Pt, resulting in PtSi), molybdenum (Mo, resulting in MoSi2), tungsten (W, resulting in WSi2), tantalum (Ta, resulting in TaSi2), Nickel (Ni, resulting in NiSi), and Nickel Platinum (Ni1-xPtx, resulting in Ni1-xPtxSi).

Siliciding may involve:
(i) depositing a suitable siliciding material (such as nickel or platinum),
(ii) performing an anneal to react said siliciding material with underlying semiconducting substrate (elevating the temperature for a period of time), and
(iii) cleaning to selectively remove unreacted siliciding material which is not on silicon. (Silicide will not form with materials such as oxide or nitride.)

A silicide is thus formed everywhere silicon (or polysilicon) is exposed. The silicide forms from the reaction of the siliciding metal and a portion of the underlying semiconducting substrate.

As the device structure evolves from generation to generation, there is now only a limited amount of substrate available for consumption. Typically, if the forming silicide consumes all the Si available, the contact area to the active part of the device will become very small and contact resistance will increase in proportion to this reduction in contact area which in most case is undesirable. This generally has a straightforward solution in which the silicon structure is made thick enough so that after siliciding there is adequate un-silicided silicon remaining to perform its intended function.

A single integrated circuit (IC) “chip” (or “die”) may comprise many millions of FETs and may measure only a few or several millimeters (mm) on a side. Several chips may be formed simultaneously, on a single “wafer”, using conventional semiconductor fabrication processes including deposition, doping, photolithography, and etching. Ultimately, the chips are separated (“singulated”) from the wafer, may be tested (either before or after singulation), and are “packaged” so that they may be incorporated into systems and interconnected with other chips and electronic components. A “package”, for example, may be a ceramic or plastic body containing the chip and having terminals on its external surface. A modern personal computer (PC), for example, may have several IC chips interconnected on a printed wiring board (PWB), with connectors for plugging in a variety of devices such as keyboards, mouses, monitors, flash memory sticks, and the like.

A deposition process may result in a “conformal” coating of material upon an underlying structure, generally meaning that it will deposit substantially evenly on all exposed surfaces. (There are some special considerations when depositing into deep or narrow trenches.) In this regard, the process may also be considered to be “isotropic”, which literally means identical (the same) in all directions. Generally, a deposition process such as such as chemical vapor deposition (CVD) or atomic layer deposition (ALD) may result in a conformal coating of material.

An etch process for removing material may also be isotropic. An example of an isotropic process is wet etch, which may be analogous to dissolving a tablet in water, wherein all surfaces of the tablet are being dissolved at once.

A deposition process may result in a “non-conformal”, coating of material upon an underlying structure, generally meaning that a coating of material is “preferentially” deposited on (for example) horizontal surfaces. In this regard, the process may also be considered to be “anisotropic”, which literally means “not the same in all directions” or “not isotropic”, or “one directional”. Generally, a deposition process such as sputtering tends to result in a non-conformal coating of material, and substantially more material may be deposited on horizontal surfaces than on vertical surfaces.

An etch process for removing material may also be anisotropic. An example of an anisotropic process is reactive ion etching (RIE), which may be analogous to sunbathing, wherein only surfaces of the body exposed to (facing in the direction of) the sun will become tanned.

Traditionally, semiconductor structures and elements have been essentially two-dimensional (2D), a sequence of layers and “flat” structures (having thicknesses, of course). For example, a conventional field effect transistor (FET) is essentially a 2D device. Contacts are made, from above, to the horizontal (top) surfaces of the source/drain diffusions, and the gate electrode. In this regard, “2D” may be considered to refer not so much to the structure of the device (of course, all physical structures are “three dimensional”), but rather to how contact is made to elements of the device.

More recently, three dimensional (3D) devices are being developed that require contact to side surfaces of the elements of the device. An example of a 3D device is the “FinFET”.

A “FinFET” is an example of a 3D device. The term FinFET was coined by University of California, Berkeley researchers to describe a non-planar, double-gate transistor built on an SOI substrate. Based on the FET, the distinguishing characteristic of the FinFET is that the conducting channel (gate) is wrapped around a thin silicon “fin”, which forms the body of the device. The dimensions of the fin determine the effective channel length of the device.

FIG. 1A illustrates, very generally, a double-gate FinFET device 100. The FinFET device 100 is essentially a silicon on insulator (SOI) device, and may be fabricated using conventional SOI fabrication processes.

Generally, a silicon “fin”, which forms the body of the device, comprises an elongated (long and narrow) polysilicon structure disposed on the surface of the substrate. The two ends of the fin may be enlarged, one end serving as the “source”, the other end serving as the “drain” of the device. A channel is defined between the source and drain.

An elongated gate structure may be disposed approximately halfway along the length of the fin (approximately midway between the source and drain), and may extend transverse to the fin, resulting in a portion of the gate being disposed on a one side of the fin, and another portion of the gate being disposed on the opposite side of the fin. The gate structure also extends over, wraps around, or “straddles” the fin, so the two portions of the gate structure are contiguous with one another. The substrate itself serves as the “second” or “back” gate in this double-gate FinFET device 100. Electrical connections (not shown) may be made to the source, the drain, and the gate. The substrate may be grounded.

As best shown in FIG. 1B, a layer of oxide 104, such as buried oxide (BOX) having a thickness of 500-1000 Å (Angstroms) may be disposed on a silicon substrate 102. A silicon layer (or SOI layer) may be disposed on top of BOX 104 using wafer bonding technique. Other processes such as separation by implanted oxygen (SIMOX) may also be used to form an SOI wafer.

A silicon fin 110 may be defined using an etching process on the SOI layer atop the BOX 104. The fin 110 may be an elongated (long, thin) structure, with a generally rectangular cross-section, having two opposite side surfaces 112a and 112b, a top edge surface 112c, and a bottom edge surface 112d opposite the top edge surface 112c. The fin 110 may have a width dimension “W” (as measured between its two side surfaces) of approximately 20-60 nm, and a height dimension “H” (as measure between its top and bottom edge surfaces) of approximately 30-100 nm.

In the channel region, the fin 110 may be surrounded by a thin layer 114 of oxide, such as thermal oxide or a “high K” dielectric layer such as a HFO2 layer. The oxide 114 may cover the top edge surface 112c, and two side surfaces 112a, 112b of the fin 110. The oxide 114 may have a thickness of approximately 1-3 nm.

In the channel region the fin 110 may be doped to have a first polarity, such as p− for a n-type transistor, and n− for a p-type transistor.

A gate structure 120 may be formed as a generally inverted U-Shaped structure which has a portion which extends over, or “straddles” the fin 110.

A first “side” portion 122a of the gate structure 120 may extend vertically (as shown) down one side surface 112a of the fin 110, to the BOX layer 104. A second “side” portion 122b of the gate structure 120 may extend vertically down the opposite side surface 112b of the fin 110, then across the BOX layer 104, away from the fin 110. A third “top” portion 122c of the gate structure 120 may be disposed atop the top edge surface 112c of the fin 110, may extend horizontally (as shown) and may join a top of the first side portion 122a of the gate structure 120 with a top of the side second portion 120b of the gate structure. The three portions 122a, 122b, 122c may be contiguous (continuous, formed integrally with one another).

A first “bottom” portion 122d of the gate structure 120 may extend from a bottom region of the first side portion 122a, horizontally, away from the fin 110, on the BOX layer 104. A second “bottom” portion 122e of the gate structure 120 may extend from a bottom region of the second side portion 122b, horizontally, away from the fin 110, on the BOX layer 104.

The gate structure 120 may have a thickness of approximately 70-100 nm. The gate structure 120 may be formed of polycrystalline silicon, and may be doped to have a polarity, such as n+ for n-type transistor and p+ for p-type transistor. Also, a metallic material such as TiN can be used as a gate.

The gate structure 120 may serve as one of two gates for the double-gate FinFET device 100. And, the substrate itself may serve as the “second” gate for the double-gate FinFET device 100. In this role, the substrate may be referred to as the “back gate”.

Contact formation is critical in reducing series resistance of a FinFET device given the 3D structure of the fin and the need to achieve appropriate current density.

FIGS. 2A and 2B illustrate two methods of making contact to the S/D regions of a FinFET device. In FIG. 2A, an over-the-fin contact provides better area scaling, with more difficult process integration, while in FIG. 2B, a “dog bone” simplifies integration.

There are two ways of making contacts that have individual pros and cons. The formation of a contact directly on the fin source/drain (S/D) itself as in FIG. 2A can be scaled to higher densities since the fin footprint is minimized. Conversely, the addition of a pad for contact in FIG. 2B can improve contact issues.

It may be preferred to make contact directly to the fin, without a contact pad—in other words, to make contact as shown in FIG. 2A. And, in general, making direct contact may benefit from silicidation of the fin.

One issue that arises in the silicidation of a 3D object, such as the fin of a FinFET, is the multiple facets available for Ni diffusion. Ni is deposited over the fin, and then annealed to diffuse the Ni into the mass of the fin. The remaining un-reacted Ni is then stripped.

Even with a small amount of deposited Ni, a fair fraction of the fin may be consumed, with the entire top portion of the fin fully silicided. As the thickness of the deposited Ni is increased, the full fin may become silicided. Consumption of an already thin fin by silicidation represents a problem, and one known solution is to add Si to the fin (prior to depositing the Ni) in the form of selective Si epitaxy, in order to prevent the full silicidation of the fin.

As is evident, some “competing forces” (design objectives) may include:

making devices smaller and smaller, so that more devices can fit in a given area

forming 3D devices, including those with thin features (such as a fin)

siliciding to improve contact

using non-conformal processes (such as sputtering) in conjunction with siliciding

avoiding consumption (by siliciding) of thin semiconductor structures.

### BRIEF SUMMARY

With the advent of three-dimensional (3D) silicon structures in semiconductor fabrication, there is a need to metallize not only the top of the structure, but also the sides of them. For purposes of this discussion, such metallization will be referred to as “silicidation”.

Silicidation generally involves deposition of a siliciding material such as nickel (Ni) on surfaces of a silicon structure, annealing to diffuse (“react”) Ni into the surface of the silicon, and then stripping unreacted Ni remaining on oxide or nitride regions where the Ni did not react.

Deposition tools commonly used for metal deposition, such as by sputtering (or evaporation), are generally non-conformal, and result in much less metal deposited on the sides of a structure (such as a fin) than on the top. The tools are generally tuned with lower pressure, higher energy, so that the bombardment of atoms is very directional. This may be beneficial for filling narrow canyons (trenches), but results in not much coverage on sidewalls. Other deposition tools such as chemical vapor deposition (CVD) or atomic layer deposition (ALD) do not have this directional problem. They are more conformal, but are not commonly used for metals.

Therefore, if you want to silicide a fin and use sputtering, for example, to deposit the metal (siliciding material), the result will be a large amount of silicide on the top (horizontal surface) of the fin and; much less silicide on vertical side(s) of the fin. In the contact geometry suggested in FIG. 2A, most of the contact area is along the sides of the fin (the top of the fin is very narrow). As a result, such a silicidation process leads to higher contact resistance since the lower part of the Fin is typically not silicided significantly.

It is a general object of the invention to provide an improved technique for forming silicide on three-dimensional (3D) structures, particularly high aspect ratio (very narrow) 3D structures, such as the silicon (Si) fins of FinFETs.

Conventional silicidation on high aspect ratio 3D structures, such as the silicon (Si) fins of FinFETs, may result in full consumption of the Si, and may not be acceptable.

According to the invention, generally, by using a non-conformal diffusion barrier in conjunction with a non-conformal initial deposition of siliciding material, a uniform and conformal silicide can be formed in a 3D structure. The 3D structure may be a fin of a FinFET, and may have a high height-to-width (H:W) aspect ratio. The siliciding material may be nickel (Ni).

An ultrathin thin diffusion barrier, to partially prevent Ni from penetrating the Si, is first deposited on the Fin. This film is not a full barrier, it only retards diffusion of Ni in proportion to its thickness. The film is deposited using similar non conformal techniques as for the subsequent Ni film deposition and its morphology will thus be similar. It is preferentially deposited thinner on vertical sidewalls of the fin and will thus allow more Ni diffusion at the sidewalls (vertical surface) than on the top of the structure (horizontal surface) where the diffusion barrier is thicker. Titanium (Ti) and Titanium Nitride (TiN) are well known diffusion barriers that can partially filter (inhibit) Ni diffusion when the films are extremely thin (˜2 nm or thinner).

Thickness and coverage control for Ti or TiN can be easily achieved by adjusting deposition conditions. The desired barrier profile is intrinsically possible by sputter deposition. The advantage of this scheme is to form a controlled uniform thickness silicide over the fin surface.

According to an embodiment of the invention, a method of siliciding a three-dimensional (3D) structure having side surfaces and a top surface comprises the steps of: depositing a layer of siliciding material on the top and side surfaces of the 3D structure, wherein depositing the layer of siliciding material comprises a non-conformal process; annealing to react at least a portion of the siliciding material into the 3D structure; and prior to depositing the layer of siliciding material, depositing a diffusion barrier layer on the 3D structure, wherein depositing the diffusion barrier layer comprises a non-conformal process so that a resulting silicidation of the 3D structure is substantially conformal. After annealing, the unreacted siliciding material may be stripped from the 3D structure. After annealing, the diffusion barrier layer may be stripped from the 3D structure.

The 3D structure may comprise a fin of a FinFET.

The siliciding material may be selected from a group of materials consisting of nickel (Ni), copper (Cu), cobalt (Co), titanium (Ti), platinum (Pt), molybdenum (Mo), tungsten (W), tantalum (Ta), nickel platinum (Nix-1Ptx) and any alloy/mix of these said materials.

The layer of siliciding material may be deposited (formed) non-conformally, with more material on the top of the 3D structure than on the sides of the 3D structure, and may be deposited by sputtering.

The diffusion barrier layer may be selected from a group of materials consisting of titanium and tantalum. The diffusion barrier layer may be selected from a group of materials consisting of silicon oxide and silicon nitride. The diffusion barrier layer may comprise a dopant.

The diffusion barrier layer may have a thickness of less than 10 Å.

Generally, the diffusion barrier layer may be formed of any material that will slow down diffusion of the siliciding material into the 3D structure, in proportion to the thickness of the diffusion barrier layer.

The diffusion barrier layer may be deposited by sputtering.

The diffusion barrier layer may be formed non-conformally, with more material on the top of the 3D structure than on the sides of the 3D structure. The diffusion barrier may be formed so that on the top surface of the 3D structure it has a thickness that is in the range of 2-10 times greater than the thickness of the diffusion barrier layer on the side surfaces of the 3D structure. The diffusion barrier may be formed so that on the top surface of the 3D structure it has a thickness in the range of 10-30 Angstroms.

According to an embodiment of the invention, a three-dimensional (3D) semiconductor structure comprises: a thin element having top surface and side surfaces, a height (H), a width (W) and a height-to-width (H/W) aspect ratio of 1 to 6; and a layer of silicide extending substantially uniformly into the top portion of the fin to a thickness of 2 to 10 nm and into the side portions of the fin to a thickness of 2 to 10 nm. The thin element of the 3D structure may comprise a fin of a FinFET.

### BRIEF DESCRIPTION OF SEVERAL VIEWS OF THE DRAWINGS

The structure, operation, and advantages of the present invention will become further apparent upon consideration of the following description taken in conjunction with the accompanying figures (FIGs.). The figures are intended to be illustrative, not limiting. Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

In some of the figures, particularly cross-sectional views of semiconductor devices in various stages of fabrication, some elements may be drawn with very straight edges intersecting with other edges at precise (such as 90-degree) angles, for illustrative clarity. One of ordinary skill in the art will appreciate that the edges may not be so straight, and the intersections may be rounded, due to the nature of the processes (such as etching) used to form the various elements of the semiconductor devices.

FIG. 1A is a perspective view of a FinFET of the prior art.

FIG. 1B is a cross-sectional view of a FinFET of the prior art.

FIG. 2A is a perspective view of a FinFET of the prior art.

FIG. 2B is a perspective view of a FinFET of the prior art.

FIG. 3A is a cross-sectional view of a first step of a process of forming a FinFET, according to an embodiment of the invention.

FIGS. 3B-3F are cross-sectional views of next steps of the process.

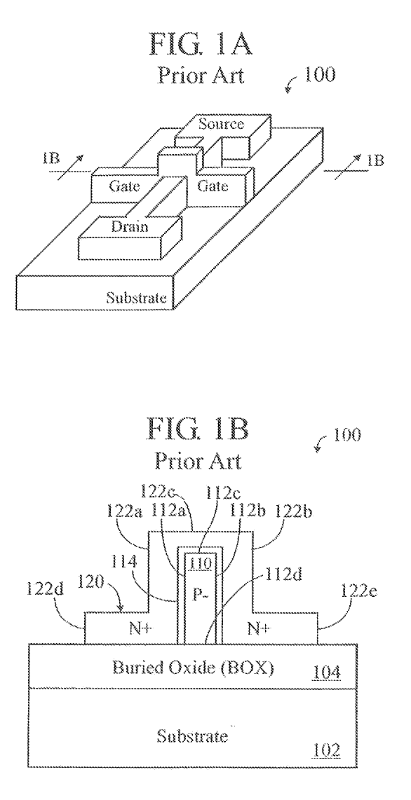

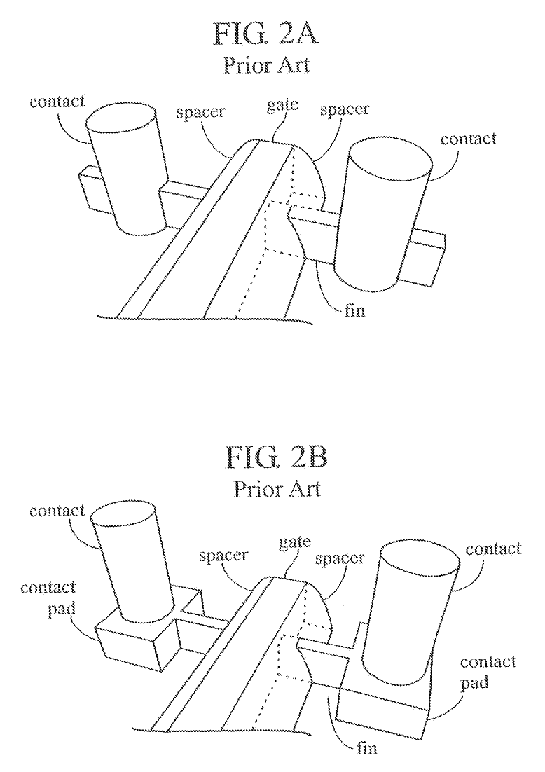

### DETAILED DESCRIPTION

In the description that follows, numerous details are set forth in order to provide a thorough understanding of the present invention. It will be appreciated by those skilled in the art that variations of these specific details are possible while still achieving the results of the present invention. Well-known processing steps and materials are generally not described in detail in order to avoid unnecessarily complicating the description of the present invention.

Materials (e.g., silicon dioxide) may be referred to by their formal and/or common names, as well as by their chemical formula. Regarding chemical formulas, numbers may be presented in normal font rather than as subscripts. For example, silicon dioxide may be referred to simply as “oxide”, chemical formula SiO2. For example, silicon nitride (stoichiometric Si3N4, often abbreviated as “SiN”) may be referred to simply as “nitride”.

In the description that follows, exemplary dimensions may be presented for an illustrative embodiment of the invention. The dimensions should not be interpreted as limiting. They are included to provide a sense of proportion. Generally speaking, it is the relationship between various elements, where they are located, their contrasting compositions, and sometimes their relative sizes that is of significance.

The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped or contain doped regions and undoped regions therein. The semiconductor substrate may contain regions with strain and regions without strain therein, or contain regions of tensile strain and compressive strain.

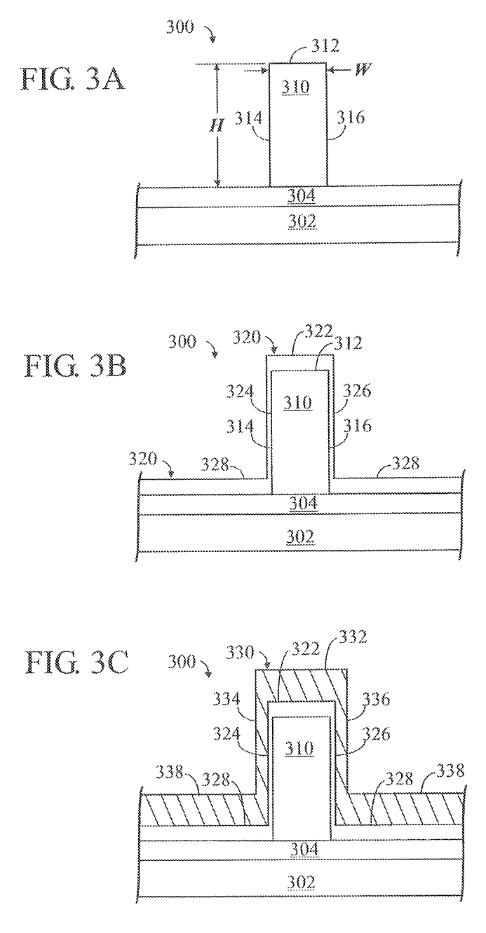

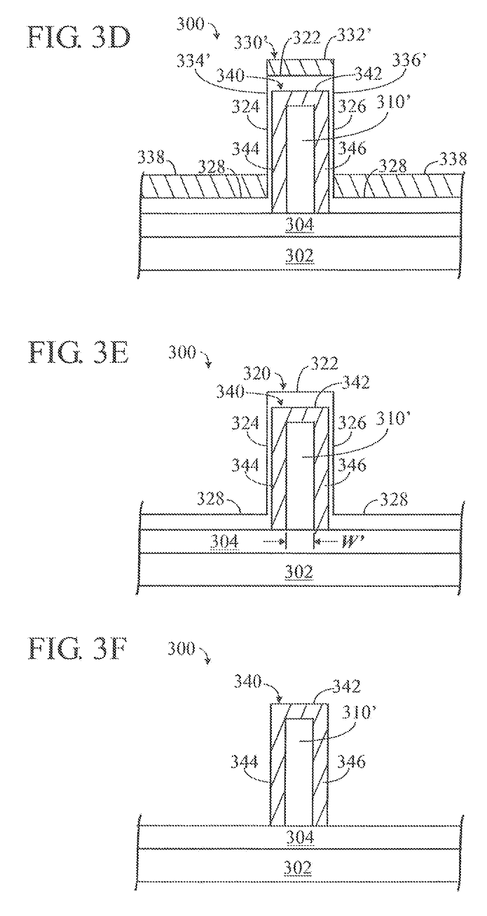

FIGS. 3A-3F illustrate a sequence of steps in an embodiment of an overall method to control silicide thickness and conformality on 3D structures, and a resulting structure (or product) resulting therefrom. Each figure may illustrate one or more steps, and in each figure an “interim” product may be illustrated.

FIG. 3A shows a representative portion 300 of an exemplary SOI semiconductor wafer, which may be referred to as the “substrate”, shown as comprising a layer 302 of silicon covered by a layer 304 of oxide (BOX), and a three-dimensional (3D) structure 310 extending upwards from a surface of the layer 304. (Alternatively, there is no BOX, and wafer, or substrate, may be bulk silicon.)

The structure 310 may be (for example) a fin of a FinFET, also formed of silicon. In the remaining hereinafter, a structure 310 which is the fin of a FinFET will be described. This “starting structure” of a fin on a layer may be considered to be a first step of the process being described. The thickness of the substrate 302 is not shown to scale.

The fin 310 has a top surface 312 and two side surfaces 314 and 316. The fin 310 has a height “H” dimension (from the layer 304 to the top surface 312), a width “W” dimension (across the top surface 312, or between the two side surfaces 314 and 316), and exhibits an aspect ratio of height-to-width (H:W). Some exemplary, non-limiting dimensions maybe: height “H”=30-100 nm, width “W”=10-30 nm, a height-to-width (H/W) aspect ratio=2-10, making it a “thin” element.

FIG. 3B shows a next step of the process. A layer 320 of material is deposited, covering the fin 310 and the substrate 302/304. The layer 320 may be formed of a material which will serve as a diffusion barrier layer for a subsequently deposited layer of material which will be used to form silicide in the fin 310. As will become evident, the non-conformality of the barrier layer 320 in conjunction with a similar non-conformality in the deposition of a subsequently deposited layer of material which will be used to form silicide in the fin 310 will cooperate to provide a substantially conformal thickness of silicide in the fin 310. Generally, the diffusion barrier 320 may be formed of any material that inhibits the diffusion of the material used to form silicide. For the diffusion barrier 320, generally, any material may be used that will slow down the diffusion, in proportion to the thickness of the diffusion barrier (i.e., slowing down the diffusion more when the diffusion barrier is thicker). Some examples of materials which may be used as the diffusion barrier include: Ti (titanium) and TiN (titanium nitride), Ta (tantalum) and TaN (tantalum nitride), which are normally used for Cu diffusion barriers (in wiring layers and damascene structures).

Normally, Ta and TaN are deposited uniformly, but to be used as the diffusion barrier (320) described herein, they would be deposited non-uniformly (non-conformally), such as by through sputtering. Alternatively, dielectric materials such as oxide (SiO) and nitride (SiN) may also be used. With oxide and nitride, the diffusion barrier layer should be formed very thin, such as having a thickness of 10 Å or less.

The diffusion barrier layer 320 may be deposited by a sputtering process, resulting in a non-conformal layer which is thicker on horizontal surfaces than on vertical surfaces.

For example, a top portion 322 of the layer 320, which is deposited on the horizontal top surface 312 of the fin 310, may have a thickness of 0.3-5 nm; side portions 324 and 326 of the layer 320, which are deposited on the vertical side surfaces 314 and 316 of the fin, respectively, may have a thickness of 0.1-2 nm or less; remaining bottom portions 328 of the layer 320, which are deposited on the horizontal surfaces of the layer 304, may have a thickness which is substantially the same as the top portion 322.

It should be noted that the thickness of the barrier layer and the deposited metal can vary along the height of the fin.

Notice that the top portion 322 of the diffusion barrier layer 320 is significantly thicker than the side portions 324 and 326. The significance and effect of this non-conformality (non-uniformity) is discussed below.

FIG. 3C shows a next step of the process. A layer 330 of material is deposited, covering the fin 310 and the substrate 302/304. The layer 330 may be formed of a material which will diffuse into the fin 310, forming silicide in the fin 310. This layer 330 will be referred to as a “siliciding” layer.

For the siliciding material (330), nickel (Ni) is usually the “first choice”, as it is conductive, known to diffuse well (quickly) into silicon, and forms an appropriate silicide (NiSi) with silicon (Si). Copper (Cu) also diffuses very well into silicon. Other siliciding materials may include:

cobalt (Co, resulting in CoSi2),

titanium (Ti, resulting in TiSi2),

platinum (Pt, resulting in PtSi),

molybdenum (Mo, resulting in MoSi2),

tungsten (W, resulting in WSi2),

tantalum (Ta, resulting in TaSi2),

nickel platinum (Ni₁₋ₓPtₓ, resulting in Ni₁₋ₓPtₓSi).

Note that these siliciding materials are generally all conductive. In the main hereinafter, a siliciding layer 330 comprising nickel (Ni) will be discussed.

The siliciding layer 330 may be deposited by a sputtering process, resulting in a non-conformal layer which is thicker on horizontal (top) surfaces than on vertical (side) surfaces. For example, a top portion 332 of the layer 330, which is deposited on the top portion 322 of the layer 320 (on the horizontal top surface 312 of the fin 310), may have a thickness of 3 to 20 nm; side portions 334 and 336 of the layer 330, which are deposited on the side portions 324 and 326 of the layer 320 (on the vertical side surfaces 314 and 316 of the fin 310), respectively, may have a thickness of 3 to 20 nm; remaining bottom portions 338 of the layer 330, which are deposited on the remaining portions 328 of the layer 320 (on the horizontal surfaces of the layer 302), may have a thickness which is substantially the same as the top portion 332.

Notice that the top portion 332 of the siliciding layer 330 is significantly thicker than the side portions 334 and 336. The significance and effect of this non-conformality (non-uniformality) is discussed below.

FIG. 3D shows a next step of the process. In this step, annealing is performed to react the nickel of the siliciding layer 330, through the diffusion barrier 320 into the silicon of the fin 310. Portions of the fin 310 will be converted to silicide (such as NiSi). For example,

a top portion 342 of the silicide 340, extending into the top portion 312 of the fin 310, may have a thickness of 3 to 20 nm.

side portions 344 and 346 of the silicide 340, extending into side portions 312 and 314 of the fin 310, respectively, may have a thickness of 3 to 20 nm, which is “substantially” the same as the top portion 342. As used herein, “substantially” means ±10-20%.

The anneal may be performed in a conventional manner, for example by elevating the temperature to 200° C.-600° C., for a period of time ranging from about 5 seconds to about 10 minutes.

Notice that the top portion 342 of the siliciding layer 340 is substantially the same thickness as the side portions 344 and 346. The significance and effect of this conformality (uniformity) is discussed below.

As a result of annealing, the fin 310′ (prime) has been modified since some of the Si was consumed by the reaction. (The diffusion barrier layer 320 may also be “modified”, but is not distinctively labeled.)

The siliciding layer 330′ (prime) has certainly been modified, and there may be some remaining (“unreacted”) siliciding layer 330′ on the barrier layer 320, including:

a top remaining portion 332′ of the siliciding layer 330′

side remaining portions 334′ and 336′ of the siliciding layer 330′

Note that the siliciding material 330 does not diffuse into the silicon 302 of the substrate, because it is covered by the buried oxide (BOX) layer 304. Thus, there is unreacted siliciding material on the barrier material deposited on the buried oxide (304).

Notice (jumping ahead to FIG. 3E) that there is an “unreacted” portion of the fin 310′, between side silicide portions 344 and 346. Whereas the fin 310 has an overall width W=10 to 30 nm and began the process as all silicon (FIG. 3A), after siliciding, outer side portions of the fin are silicide, and the unreacted central portion of the fin 310′ has a width W′ (prime) that is smaller than the original fin since some of the silicon was consumed by the siliciding reaction. The thickness of silicon that is consumed is dependent on the amount and phase of silicide formed which depends on the thickness of siliciding material and the efficacy of the partial diffusion barrier.

FIG. 3E shows a next step of the process. In this step, any unreacted (leftover) metal (Ni) of the siliciding layer 330′ is removed. If the diffusion barrier layer 320 is formed of a dielectric material (non conducting material), such as oxide or nitride, it may be left in place. As shown in FIG. 3F, if the diffusion barrier layer 320 was formed of a conductive material, it is removed.

Conformal Silicide Resulting from Non-Conformal Depositions

There has thus been shown a process for forming conformal (substantially uniform thickness) silicide on 3D structures.

As mentioned above, the top portion 322 and 332 of the diffusion barrier 320 and siliciding layer 330, respectively, are significantly thicker than the side portions 324/326 and 334/336. Both are substantially thicker at the top (on the horizontal surface) than on the sides (on the vertical surfaces).

In this manner, a non-conformal process leads to a conformal formation of silicide.

(non-conformal barrier)+(non-conformal nickel)+(anneal)=(conformal silicide)

Generally, the non-conformal process (such as sputtering) used to deposit the siliciding material (such as nickel) may be substantially similar to the non-conformal process used to deposit the barrier layer, so that the coverage of the 3D structure by these materials is substantially similar—namely thick on the top and thin on the sides—which will result in a substantially conformal silicidation of the 3D structure.

Diffusion barriers are usually used to completely block diffusion. According to an aspect of the invention, the diffusion barrier 320 is not used to completely block the diffusion (of Ni 330), but rather to inhibit it, and slow it down. In this respect it is considerably thinner than complete diffusion barriers typically used in the industry. In the manner suggested here, the non-conformal diffusion barrier 320 works in conjunction with the subsequent non-conformal siliciding material layer 330 to achieve conformal silicidation in the fin 310.

In order to achieve the desired conformal silicide in the surface of the fin (310) from an initial non-conformal coating of siliciding material (330) on the fin, the thickness (Ttop) of the top portion 322 of the diffusion barrier 320 may be ranging from 2 to about 10 times more than the thickness (Tside) of the side portions 324 and 326 of the diffusion barrier 320. In other words, Ttop/Tside>2:1, including up to about 10:1.

Some “practical” numbers for thickness of the diffusion barrier 320 are 0.3-5 nm on the top 312 of the fin 310, and the aforementioned ratio of Ttop/Tside>2:1, including up to at least 10:1.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A method of siliciding a three-dimensional (3D) structure having side surfaces and a top surface comprising the steps of:
depositing a layer of siliciding material on the top and side surfaces of the 3D structure, wherein depositing the layer of siliciding material comprises a non-conformal deposition process;
annealing to react at least a portion of the siliciding material into the 3D structure; and
prior to depositing the layer of siliciding material, depositing a diffusion barrier layer on the 3D structure, wherein depositing the diffusion barrier layer comprises a non-conformal deposition process so that a resulting silicidation of the 3D structure is substantially conformal.

2. The method of claim 1, further comprising the step of stripping off unreacted siliciding material from the 3D structure after said annealing.

3. The method of claim 1, further comprising the step of stripping off the diffusion barrier layer from the 3D structure after said annealing.

4. The method of claim 1, wherein the 3D structure comprises a fin of a FinFET.

5. The method of claim 1, further comprising the step of selecting the siliciding material from a group of materials consisting of nickel (Ni), copper (Cu), cobalt (Co), titanium (Ti), platinum (Pt), molybdenum (Mo), tungsten (W), tantalum (Ta), nickel platinum (Niₓ₋₁Ptₓ) and any alloy/mix thereof.

6. The method of claim 1, further comprising the step of depositing the layer of siliciding material non-conformally, with more said siliciding material on the top of the 3D structure than on the side of the 3D structure.

7. The method of claim 6, further comprising the step of depositing the layer of siliciding material by a sputtering process.

8. The method of claim 1, further comprising the step of selecting material for the diffusion barrier layer from a group of materials consisting of titanium, titanium-nitride, tantalum, and tantalum-nitride.

9. The method of claim 1, further comprising the step of selecting material for the diffusion barrier layer from a dielectric material, said dielectric material being selected from a group consisting of silicon oxide and silicon nitride.

10. The method of claim 1, further comprising the step of forming the diffusion barrier layer to have a thickness of less than 10 Å.

11. The method of claim 1, further comprising the step of forming the diffusion barrier layer with a dopant.

12. The method of claim 1, further comprising the step of forming the diffusion barrier layer with a material, said material will slow down diffusion of the siliciding material into the 3D structure, in proportion to the thickness of the diffusion barrier layer.

13. The method of claim 12, further comprising the step of depositing the diffusion barrier layer non-conformally, with more diffusion barring material on the top of the 3D structure than on the sides of the 3D structure.

14. The method of claim 13, further comprising the step of depositing the diffusion barrier layer by a sputtering process.

15. The method of claim 12, further comprising the step of forming the diffusion barrier layer on the top surface of the 3D structure with a thickness which is greater than a thickness the diffusion barrier layer formed on the side surfaces of the 3D structure.

16. The method of claim 15, further comprising the step of forming the diffusion barrier layer on the top surface of the 3D structure with a thickness that is in the range of 2-10 times greater than the thickness of the diffusion barrier layer on the side surfaces of the 3D structure.

17. The method of claim 16, further comprising the step of forming the diffusion barrier layer on the top surface of the 3D structure to a thickness in the range of 10-30 Angstroms.

18. The method of claim 1, comprising the steps of:
forming the 3D structure as a fin of a FinFET;
forming the diffusion barrier layer by:
depositing a diffusion barrier layer on the top portion of a horizontal top surface of the fin and on vertical side surfaces of the fin to a thickness of 0.1 to 5 nm; and
forming the layer of siliciding material by:
depositing siliciding material on a top portion of the diffusion barrier layer to a thickness of 2 to 15 nm; and
depositing siliciding material on the diffusion barrier layer on the vertical side surfaces to a thickness of 0.1 to 5 nm.

19. A three-dimensional (3D) semiconductor structure comprising:
a thin element having a top surface and side surfaces, a height (H), a width (W) and a height-to-width (H/W) aspect ratio of 1 to 6; and
a layer of silicide extending substantially uniformly into the top portion and side portions of the fin to a thickness of 2 to 10 nm.

20. The 3D semiconductor structure of claim 19, wherein:
the thin element of the 3D structure is a fin of a FinFET.
